(19) United States
(12) Patent Application Publication
(10) Pub. No.: US 2025/0122118 A1
(43) Pub. Date: Apr. 17, 2025

(54) Modifying Stress on Using Pre-Bend of Substrates Supporting CVD Deposited Diamond

(71) Applicant: AKHAN Semiconductor, Inc., Gurnee, IL (US)

(72) Inventors: Maria Cristina Maugeri, Westmont, IL (US); Craig Steven Mitchell, San Jose, CA (US); Ernest Schirmann, Lake Zurich, IL (US); Kiran Kumar Kovi, Lisle, IL (US); Debarati Mukherjee, Libertyville, IL (US)

(21) Appl. No.: 18/911,003

(22) Filed: Oct. 9, 2024

Related U.S. Application Data
(60) Provisional application No. 63/589,504, filed on Oct. 11, 2023.

(51) Int. Cl. C03C 17/34; C03B 23/023; C03C 21/00; C23C 16/02; C23C 16/27

(52) U.S. Cl. CPC C03C 17/3441; C03B 23/023; C03C 21/002; C23C 16/02; C23C 16/27; C03C 2217/213; C03C 2217/28; C03C 2217/70; C03C 2218/152; C03C 2218/31; C03C 2218/365

(57) ABSTRACT

A method of forming a diamond coated glass structure includes providing a glass substrate having a first and a second side. The second side can be covered in whole or in part with a coating capable of reducing ion exchange. The substrate can be bent to form the first side as convex and the second side as concave. A CVD diamond layer can be deposited on the convex first side of the substrate and at least a portion of the substrate chemically modified through ion exchange. After removal of the stress, the stresses due to applied diamond layers and chemical modification through ion exchange can balance, providing a substantially flat diamond coated glass structure.

### RELATED APPLICATION

This application claims the priority benefit of U.S. Provisional Patent Application No. 63/589,504, filed on Oct. 11, 2023, which is hereby incorporated by reference in its entirety.

### FIELD OF THE INVENTION

This invention is generally related to systems and methods for diamond coating of chemically modified or ion exchanged glass using chemical vapor deposition (CVD). In one embodiment, glass substrate flatness is preserved by coating at least one side of a glass substrate with diamond to increase glass hardness and durability only after pre-bending the glass substrate.

### BACKGROUND

Diamond films or coatings can be used for protecting optical systems, coatings for consumer applications such smartphone or watch displays, coatings for tooling or mechanical parts, coatings for chemical protection, or in electrical or semiconductor applications. Advantageously, diamond films provide increased hardness, scratch resistance, water resistance, and various unique electrical properties.

Unfortunately, diamond deposition can result in flat glass being warped due to stress attributable to the applied diamond or other films. What is needed are glass structures and processing techniques that reduce such warping while retaining the advantages of diamond coating.

### SUMMARY

Disclosed herein is a new and improved system and method for a diamond coating using CVD systems. A method of forming a diamond coated glass structure includes providing a glass substrate having a first and a second side. The second side can be covered in whole or in part with a coating capable of reducing ion exchange. The substrate can be bent to form the first side as convex and the second side as concave. A CVD diamond layer can be deposited on the convex first side of the substrate and at least a portion of the substrate chemically modified through ion exchange. After removal of the stress, the stresses due to applied diamond layers and chemical modification through ion exchange can balance, providing a substantially flat diamond coated glass structure.

In some embodiments, bending the substrate uses asymmetrically applied mechanical force.

In some embodiments, bending the substrate uses thermal heating of the substrate

In some embodiments, the coating capable of reducing ion exchange is silicon dioxide.

In some embodiments, at least one of nanocrystalline and ultrananocrystalline diamond is deposited on the convex first side of the substrate.

In some embodiments, chemically modifying the substrate through ion exchange comprises replacement of at least some sodium ions with potassium ions.

In another embodiment, a diamond coated glass structure suitable for chemical modification by ion exchange can include a glass substrate having a first and a second side. A coating capable of reducing ion exchange is applied to at least a portion of the second side and a CVD diamond layer is applied to at least a portion of the first side of the glass substrate. Prior to ion exchange, the glass substrate is bent to form the first side as convex and the second side as concave.

In some embodiments, the CVD diamond layer comprises at least one of nanocrystalline and ultrananocrystalline diamond.

In some embodiments, the CVD deposited diamond layer comprises a nanocrystalline diamond layer having thickness between 20 and 500 nanometers.

In some embodiments, the CVD deposited diamond layer comprises a 100-500 nanometer thick CVD deposited diamond layer having at least 50% of diamond grains sized between 10 nanometers and 150 nanometers.

In some embodiments, the ultrananocrystalline diamond layer has thickness up to 50 nanometers.

In some embodiments, combination of the CVD deposited diamond layer and the glass substrate provides transmission of light with a transmissivity in excess of at least one of 0.80 at wavelengths ranging between 500 and 600 nanometers.

In some embodiments, the glass substrate has a dimension of at least one centimeter.

In some embodiments, the glass substrate comprises at least one of a soda lime glass, aluminosilicate glass, and borosilicate glass.

In some embodiments, the glass substrate is chemically modified by replacement of at least some sodium ions with potassium ions.

Other systems, methods, aspects, features, embodiments and advantages of the system and method disclosed herein will be, or will become, apparent to one having ordinary skill in the art upon examination of the following drawings and detailed description. It is intended that all such additional systems, methods, aspects, features, embodiments and advantages be included within this description, and be within the scope of the accompanying claims.

### BRIEF DESCRIPTION OF THE DRAWINGS

It is to be understood that the drawings are solely for the purpose of illustration. Furthermore, the components in the figures are not necessarily to scale, emphasis instead being placed upon illustrating the principles of the system disclosed herein. In the figures, like reference numerals designate corresponding parts throughout the different views.

FIG. 1A is an exemplary schematic diagram of a system and method 100A for coating a glass substrate with nanocrystalline (NCD) and/or ultrananocrystalline (UCD) diamond layers in a manner that can increase glass substrate strength and improve flatness;

FIGS. 1B(i-iv) illustrate bendable convex diamond coated structures capable of being chemically modified through ion exchange; and

FIG. 1C illustrates a bendable concave diamond coated structure capable of being chemically modified through ion exchange.

### DETAILED DESCRIPTION

The following detailed description, which references to and incorporates the drawings, describes and illustrates one or more specific embodiments. These embodiments, offered not to limit, but only to exemplify and teach, are shown and described in sufficient detail to enable those skilled in the art to practice what is claimed. Thus, for the sake of brevity, the description may omit certain information known to those of skill in the art.

As used in this disclosure, the terms “layer”, “film”, and “coated” can be interchangeably used, and refer to thin deposited, chemically formed, grown materials, or otherwise situated materials on a substrate that can itself be a layer, film or coating. Diamond layers or films can include intrinsic diamond, diamond-like material, or diamond with small amounts of graphite or other materials. Diamond lattice structure can be selectively modified and can include provision of varying sp2/sp3 carbon materials positioned through selective seeding or etch, nucleation or growth process parameters including gas composition, pressure, and temperature among other parameters, selective laser annealing, particle bombardment or doping, or use of laser pulse to grow diamond. Modification of diamond layers or films by oxygen termination, hydrogen termination, chlorine or fluorine functionalization are additional embodiments.

The diamond structure and manufacturing method described herein can incorporate systems and methods previously disclosed and described in U.S. Patent Publication No. 2013/0026492, by Adam Khan, published on Jan. 31, 2013; U.S. Pat. No. 8,354,290, issued to Anirudha Sumant, et al, on Jan. 15, 2013; U.S. Pat. No. 8,933,462, issued to Adam Khan on Jan. 13, 2015; U.S. Patent Publication No. 2015/0206749, by Adam Khan, published on Jul. 23, 2015; and U.S. Patent Publication No. 2015/0295134, by Adam Khan, et al, published on Oct. 15, 2015, all of which are fully incorporated herein by reference.

In one embodiment, glass warping of diamond coated glass can occur after an ion exchange process. As used herein, the term “ion exchange” or “ion substitution” is understood to mean that the glass is capable of being chemically modified by ion exchange processes that are known to those skilled in the art. Such ion exchange processes include, but are not limited to, treating a glass article with a solution containing ions having a larger ionic radius than that of the ions that are present in the glass, replacing the smaller ions with the larger ions. In one embodiment of this process, at least some ions of a first element in a surface region in the glass article are exchanged with ions of a second element, wherein each of the ions of the second element has an ionic radius that is greater than that of the ion of the first element that is being replaced. In one embodiment, the first and second elements are alkali metals. The replacement of sodium (Na+ ions) with potassium (K+ ions) is a non-limiting example of such an ion exchange. Alternatively, other alkali metal ions having larger atomic radii, such as rubidium or cesium, could replace smaller alkali metal ions in the glass. In another embodiment, the smaller alkali metal ions could be replaced by silver (Ag+) ions. In some embodiments, additional elements such as Li+, Rb+, Cs+, Cd2+, Zn2+ or Cu+/Cu2+ can be used. As will be understood, ion exchange can be done before or after diamond coating, and multiple ion exchange events can occur during glass processing.

Ion exchange may be carried out using those methods known in the art and described herein. Depending on ion penetrance depth and other characteristics, chemical modification by ion exchange of a glass substrate can result in glass strengthening, hardening, or both. In one embodiment, the glass is immersed in a molten salt bath comprising an alkali metal salt such as, for example, potassium nitrate (KNO₃), for a predetermined time period to achieve ion exchange. In some embodiments, the glass substrate can be chemically modified in a single ion exchange step. In some embodiments, the glass substrate is immersed in a molten salt bath containing a salt of the larger alkali metal cation. In some embodiments, the molten salt bath contains or consists essentially of salts of the larger alkali metal cation. In some embodiments single ion exchange process may take place at a temperature below 600° C., while in other embodiments the temperature can be between 275° C. and 550° C. for a time sufficient to achieve the desired ion depth penetrance (which in some embodiments can be increased as thickness of glass increases, and in some embodiments can be between 5 and 300 microns).

In another embodiment, a glass substrate can be chemically modified in a two-step or dual ion exchange method. In the first step of this process embodiment, the glass substrate is processed through a first ion exchange in a first molten salt bath. After completion of the first ion exchange, the glass can be optionally diamond coated, and then immersed in additional ion exchange baths (e.g., a second ion exchange bath). Additional or second ion exchange baths can have the same composition as the first ion exchange bath. Alternatively, additional or second ion exchange baths can have different compositions and/or operated at differing immersion time lengths and temperatures than the first ion exchange bath.

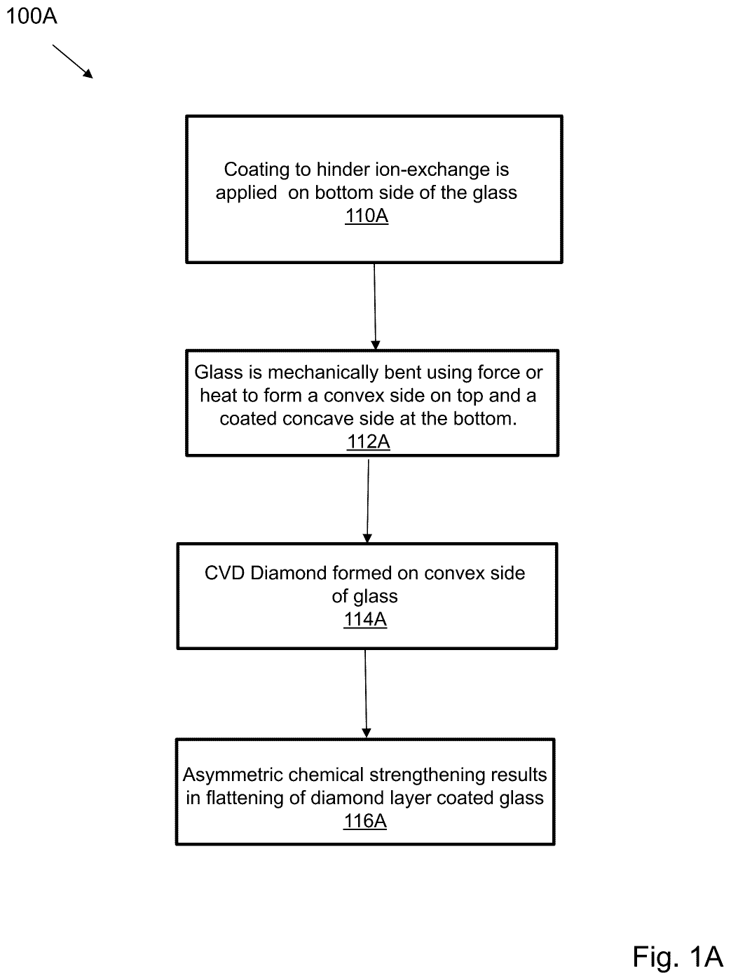

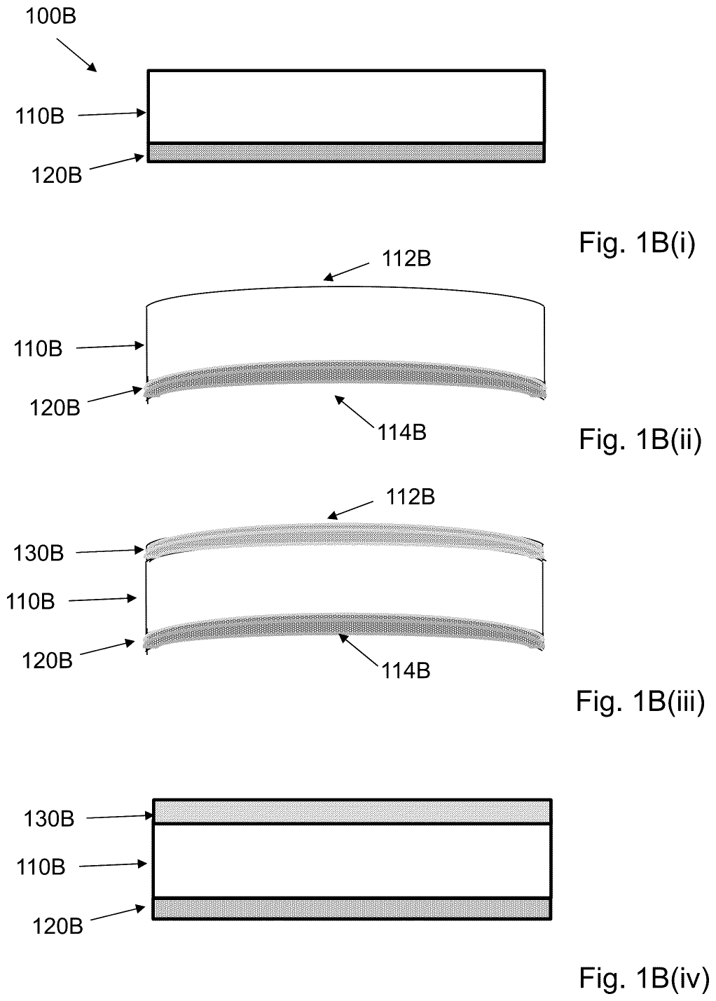

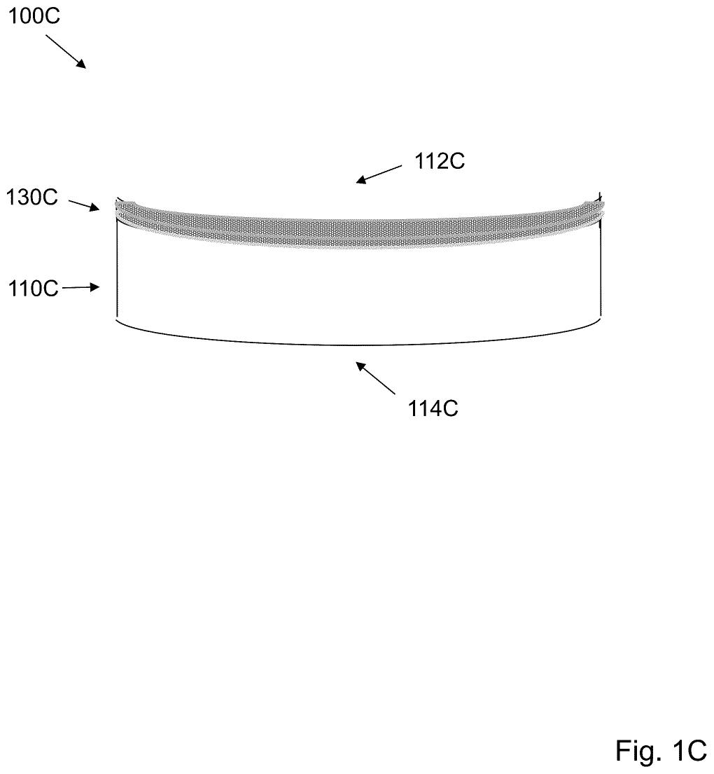

FIG. 1A is an exemplary schematic diagram of a system and method 100A for coating a glass substrate with nanocrystalline (NCD) and/or ultrananocrystalline (UCD) diamond layers in a manner that can increase glass substrate strength and improve flatness. As illustrated with respect to FIG. 1A, a system and method 100A provided herein allow manufacture of substantially flat diamond coated glass structures having a glass substrate with first (top) and second (bottom) sides. In the first step 110A, a coating able to hinder or reduce ion exchange is applied to the second or bottom side. In a second step 112A, the glass substrate can be bent using applied mechanical force or thermal heating to form a convex side on top side and a coated concave side at the bottom side. In a third step 114A, the glass substrate has CVD diamond formed or otherwise deposited on the top convex side of the glass substrate. In step 116A, the glass substrate is subjected to asymmetric ion exchange, with differing ion exchange effects between top and bottom of the glass substrate. After ion exchange, the previously curved diamond coated glass structure will be flat, or substantially flat, with the diamond coated top surface being chemically strengthened. In effect, the chemically strengthened diamond surface tends to warp upwards due to the higher compressive stress as compared to the bottom glass surface, which has little to no compressive stress. Such tendency causes the curvature induced prior to the ion exchange to be countered. As will be understood, in some embodiments the coating hindering ion exchange can be stripped or otherwise removed from the bottom of the substrate.

In some embodiments, diamond coated glass articles that have undergone ion exchange can further be formed to support multilayer structures, anti-reflective coating film stacks, or other coatings such as may be provided to enhance hydrophobicity or oleophobicity. In some embodiments, the CVD diamond coated glass substrate is flat, or substantially flat, with high scratch resistance on the top diamond coated surface, with most impact resistance at the corners, lower impact resistance at the edges and lowest impact resistance in the central regions. In other embodiments, the CVD diamond coated glass substrate can be curved, etched, molded, or otherwise formed into a desired shape. Any coatings applied before the ion exchange to promote asymmetric strengthening can be removed in whole or in part, or alternatively allowed to remain as part of a final structure. Advantageously, use of these methods or structures can provide a CVD diamond coated glass substrate well suited for display or optical equipment, including smartphones, tablets, laptops, automotive windshields, or optical lenses or sensors.

FIGS. 1B(i-iv) are exemplary schematic diagrams of various intermediate structures used to form a glass substrate coated with nanocrystalline (NCD) and/or ultrananocrystalline (UCD) diamond layers using a method such as described with respect to FIG. 1A. As illustrated in FIG. 1B(i), a glass structure 100B includes a glass substrate 110B. A first or top surface 112B of the glass substrate 110B and a second or bottom surface 114B are provided to support coatings. In some embodiments, such coatings can include but are not limited to single or multiple layers of diamond, silicon dioxide, silicon oxynitride (SiOₓN_{y} where x and y can vary), or silicon nitride (SiₓN_{y}, where x and y can vary). In some embodiments, a coating can act to improve adhesion over later coatings.

As illustrated in FIG. 1B (ii), the glass substrate is mechanically bent using force or heat to form a convex side on top side and a coated concave side at the bottom side. Permanent or temporary coatings 120B can be applied to all or portions of a bottom of a glass substrate 110B. Typically, the coating 120B can be silicon dioxide or other coating selected to hinder but not completely block ion- diffusion into the glass substrate. In some embodiment, the coating 120B can be applied to glass substrate central region, while corners and edges remain uncoated. In some embodiments, different coating thicknesses can be used locally so that after ion exchange portions of the substrate defined by straight edges will have a higher compressive strength than central regions (both top and bottom) while corners will obtain a higher compressive strength than the edges.

As illustrated in FIG. 1B(iii), a nanocrystalline (NCD) and/or ultrananocrystalline (UCD) diamond layer 130B that fully or partially covers the top surface 112B glass substrate 110B can be formed using CVD deposition. In some embodiments, other coatings such as antireflective, oleophobic, or hydrophobic coatings can be added on the diamond layer 130B.

As illustrated in FIG. 1B(iv), the glass substrate 110B can have mechanical force removed and subjected to asymmetric ion exchange, with differing ion exchange effects between top 112B and bottom 114B of the glass substrate. After ion exchange, the previously curved diamond coated glass structure will be flat, or substantially flat, with the diamond coated top surface being chemically strengthened.

FIG. 1C illustrates a bendable concave diamond coated structure 100C capable of being chemically modified through ion exchange. As shown, pre-bending a substrate 110C can define a structure with a concave first side 112C and convex second side 114C. The first side 112C can be coated with CVD diamond 130C formed or otherwise deposited on the first concave side of the substrate 110C. The glass substrate can be subjected to asymmetric ion exchange, with differing ion exchange effects between first and second sides of the substrate. After ion exchange, the previously curved diamond coated glass structure will be flat, or substantially flat, with the second side of the substrate surface being chemically strengthened to a greater degree than the first surface 112C of the substrate 110C.

As will be understood, various types of glass substrates can be used in structures. For example, the glass can be a silicate glass, such as an alkali silicate glass, soda lime glass, an alkali aluminosilicate glass, an aluminosilicate glass, a borosilicate glass, an alkali aluminogermanate glass, an alkali germanate glass, an alkali gallogermanate glass, and combinations thereof. Structures can also be fabricated on infrared (IR) substrate materials including but not limited to Silicon (Si), Zinc Sulfide (ZnS), Zinc Selenide (ZnSe), Germanium (Ge), Magnesium Fluoride (MGF₂), Sapphire (Al₂O₃), Aluminum Oxynitride (AlₓO_{y}N_{z}), Spinel (MgAl₂O₄), Calcium Fluoride (CaF₂), Sodium Chloride (NaCl). In some embodiments, multiple types of glass or IR materials can be fused or layered together to provide a substrate. Other examples of glass types and compositions suitable for use are described more fully in U.S. Pat. No. 8,232,218, assigned to Corning, Inc.

Glass substrate thickness can be less than 5 mm and, in some embodiments, have a thickness between 0.5 and 3 mm. In particularly thin embodiments, the thickness of the glass substrate can be between 0.3 and 1 mm. In some embodiments, thickness of a glass substrate can be between 0.25-3 mm. In other embodiments, thickness can be less than 2 mm, less than 1 mm, or less than 0.6 mm. In some embodiments, the glass substrate of the thickness described herein can have horizontally extending dimensions (i.e. not thickness) of one centimeter or greater.

In one embodiment, forming glass substrate edges to correspond to a particular predetermined geometry and providing chemical modification can cause compression in the vicinity of the edges of the glass cover to be enhanced. The glass cover can thereby be made stronger by imposing the particular predetermined geometry on the edges of the glass cover. In one embodiment, surfaces, e.g., edges, of the glass cover can be chemically modified. In one embodiment, the edge geometry is configured to reduce or smooth out sharp transitions, such as corners.

In some embodiments one or more edges of the glass substrate can be curved or chamfered. A chamfer is a beveled edge that substantially connects two sides or surfaces (e.g., top and bottom surfaces). By way of example, edge geometry may include a chamfered edge of between 0.2 millimeter and 0.5 millimeters, extending at least partially between top and bottom sides of the glass substrate. Advantageously, use of the chamfered edge can reduce compressive stresses. Alternatively or in addition, in one embodiment, a glass substrate edge can include a smoothed corner, where for example a corner between a first surface and a second surface (e.g., top/bottom surface and a side surface that is substantially perpendicular) can be rendered less sharp. As another example, transition between a top surface to a side surface or between a bottom surface and a side surface can be smoothed. In some embodiments, edges of glass can be rounded by a predetermined edge geometry having a predetermined edge radius (or predetermined curvature) of at least 10% of the thickness applied to the corners of the edges of the glass. In other embodiments, the predetermined edge radius can be between 20% to 50% of the thickness of the glass. In one embodiment, a glass cover can extend to the edge of a housing of an electronic device without a protective bezel or other barrier. In one embodiment, the glass cover can include a bezel that surrounds the respective edges. The glass cover can be provided over or integrated with a display, such as a Liquid Crystal Display (LCD) display usable in a smartphone, watch, or tablet.

In some embodiments, a glass substrate structure can be subject to optional processing steps. Such processing steps can include applying one or more additional coatings or laminates (e.g., organic, polymer, inorganic, or graphene) to the glass substrate. In some embodiments, the entire substrate can have additional coatings, while in other embodiments at least one of a top, bottom, edge, or corner of the glass substrate can be provided with coatings.

In some embodiments, before deposition of a diamond or diamond like coating or film, a substrate can be treated by sputtering, evaporation, atomic layer deposition (ALD), chemical vapor deposition, plasma, thermal form of deposition of one or more of materials including but not limited to oxides and nitride dielectric materials, oxides of metals such as titanium, indium, tin, zinc, or combinations, oxides of graphene such as graphene oxide, reduced fluorinated graphene oxide, oxides of silicon, titanium, or aluminum, oxynitrides, nitrides of aluminum, silicon, titanium, boron, and metals such as tungsten or titanium. These intermediate materials can enable or enhance 1) adhesion of subsequent layers, 2) system optical properties such as transmission and reflection, 3) system stress through of thermal coefficient of enhancement transitioning, 4) reduced surface roughness, and other properties. In some embodiments, for metal deposited via sputter deposition, power levels can be adjusted, and shutter opening times can vary to achieve the target thickness uniformly across the display glass surface. For oxides and nitrides, thin films may utilize lower temperature (including temperatures less than or equal to 600° C.). Advantageously in some embodiments this can reduce coefficient of thermal expansion differences, reducing interlayer and subsurface stress, and allow for tuning coloration and visual uniformity, as well as optical losses attributable to haze or reflectance.

To encourage growth of diamond layers or films with selected grain sizes or in defined areas, a substrate can be seeded with diamond crystal particulates. Seed layers can be formed through the use of selective deposition or etched seed areas. In some embodiments, nanocrystalline diamonds can be directly deposited or deposited in a solution. In some embodiments, seed size can range from 5 to 50 nanometers. Seeds can be functionalized, or can have a positive, negative, or neutral zeta potential. The seed crystals may be in a solvent, dimethyl sulfoxide, oil, photoresist, deionized water, a combination or similar types of suspension or matrix. Substrate coverage with diamond crystal seeds can be uniformly distributed at 10⁵-10¹³ grains per square centimeter, non-uniform, or localized in selected areas using masks, selective spraying, electrospraying, ultrasonic spraying, sonication, or other form of spatially localized application. In some embodiments seeds of differing sizes and characteristics can be used.

In some embodiments, a diamond layer formed on a diamond seeded substrate can have a sp² concentration of less than 20% by diamond layer volume. In other embodiments, a diamond layer can have a grain orientation at least 80% in either the <111> or <100> crystalline direction. In still other embodiments, a highly oriented diamond film can include differing crystal orientations in selected region or layers, with <111> and <100> crystalline direction respectively predominating.

Properties of diamond can be measured and characterized using Raman spectroscopy. Cubic diamond has a single Raman-active first order phonon mode at the center of the Brillouin zone. The presence of sharp Raman lines allows cubic diamond to be recognized against a background of graphitic or other carbon crystal types. Small shifts in the band wavenumber can indicate diamond composition and properties. In some embodiments, the full width half maximum (FWHM) obtained from Raman characterization at a wave number of 1332 cm⁻¹ for the diamond layers or films formed as indicated in this disclosure can be between 5 and 20 cm⁻¹ for SiN or other suitable buffer layer coated glass and between 20 and 85 cm⁻¹ for RIE (reactive ion etched) or other surface treated glass. In other embodiments, a deposited diamond layer can be measured to have a relative magnitude at 1332 cm⁻¹ and greater than or equal to 0.5:1 as compared to magnitude at 1400-1600 cm⁻¹ by Raman analysis. In other embodiments, a diamond layer can have physical properties such as Vickers hardness measured by nanoindentation of at least 12 Gigapascal. In other embodiments Vickers hardness can be greater than 20 Gigapascal. In other embodiments, a diamond layer can be measured to exert a compressive stress less than 50 Gigapascal.

In some embodiments, polycrystalline diamond or diamond-like carbon (DLC) coatings or materials can be formed on all or at least a portion of a substrate. In some embodiments, polycrystalline diamond grains sized to be less than 1 micron (1000 nanometers) and greater than 500 nanometers can be used. In other embodiments, polycrystalline diamond or diamond-like material can include ultrananocrystalline (UNCD) grain sizes (2-10 nanometers), nanocrystalline grain sizes (10-500 nanometers), or microcrystalline grain sizes (500 nanometers or greater). In some embodiments, diamond grain size can include a range of grain sizes, including larger and smaller grains. In some embodiments, a diamond layer can be formed to have grains of less than 1 micron. In some embodiments, grain size can differ by greater or less than 50%, 100%, 200% or 500% of mean diamond grain size. In other embodiments, diamond grain size can be maintained to within 50%, 20%, or 10% of mean grain size. In some embodiments, 50%, 60%, 80%, or 90% of the diamond grains can be sized between 50 and 500 nanometers. In some embodiments, a diamond layer can be formed from at least 90% nanocrystalline diamond and have diamond grains sized between 2 nanometers and 500 nanometers. In some embodiments, a diamond layer can be formed from at least 90% microcrystalline diamond and have diamond grains sized between 500 nanometers and 1000 nanometers. In other embodiments, diamond grains can be sized between 500 nanometers and 1000 nanometers. In other embodiments, 90% of the diamond grains can be sized between 200 and 300 nanometers.

Diamond layer thickness in some embodiments can be selected to be between 20 nanometers and 1000 nanometers. Typically diamond grain size will be 50% or less of diamond layer thickness. In some embodiments useful for optical coatings, diamond layer thickness will be between 20 and 500 nanometers. For example, in one embodiment a glass or other transparent material can be coated with a diamond film having a thickness between 100 and 300 nanometer thickness.

Diamond layers can have a substantially uniform thickness over all or defined portions of a surface or substrate. In other embodiments, thickness can be non-uniform and vary over portions of a surface or substrate. In some embodiments diamond layers can be conformal when extending over cavities, depressions, or protrusions in a substrate or surface. In some embodiments, diamond layers can steadily thin or thicken away from one or more positions on a substrate.

Multiple diamond layers distinguished by composition, crystal structure, dopants, grain size, or grain size distribution can be a part of a multilayer coating or film system applied to a substrate. Distinct diamond layers can be layered on top of diamond layers or non-diamond materials. In certain embodiments, physical parameters of diamond layers can continuously or semi-continuously change vertically or laterally through the layer.

In particular embodiments, the diamond layer has a thickness, for example, between 30nanometers and 150 nanometers (e.g., 30 nanometers, 40 nanometers, 50 nanometers, 60 nanometers, 70 nanometers, 80 nanometers, 90 nanometers, 100 nanometers, 110 nanometers, 120 nanometers, 130 nanometers, 140 nanometers, or 150 nanometers inclusive of all ranges and values there between). Furthermore, the diamond layer can have a root mean square (RMS) surface roughness of less than 2 nanometers

Diamond or DLC can be deposited by chemical vapor deposition (CVD) such as hot filament CVD, microwave CVD, rf-CVD, laser CVD (LCVD), or laser ablation, metal-organic CVD (MOCVD), sputtering, thermal evaporation PVD, ionized metal PVD (IMPVD), electron beam PVD (EBPVD), reactive PVD, cathodic arc, and the like. CVD involves the use of a diluted mixture of a carbon containing gas such as carbon dioxide or hydrocarbons, typically methane, and hydrogen whereby the carbon containing component content usually varies from about 0.1% to 4% of the total volumetric flow. In one of these techniques, the gas mixture is energized using a metallic filament (which can be tungsten) that is electrically heated to a temperature ranging from about 170° C. to 2400° C. The gas mixture disassociates at the filament surface and carbon, hybridized in the form of diamond, is deposited onto a substrate placed below the filament. In operation, power density at the substrate can be between 300-600 W/m2/min. Deposition usually occurs at sub-atmospheric pressures in the range of 30 mTorr to 300 Torr.

In some embodiments, a thin diamond film can be deposited on a substrate having a substrate temperature of less than 600 degrees Celsius. In other embodiments, deposition can be at temperatures between 300 and 600 degrees Celsius. Advantageously, as compared to typical 700-800 degree Celsius temperatures for conventional CVD mediated diamond film growth, such low temperatures greatly reduce thermal effects, including thermal degradation, stress due to differing CTE, or warping of the substrate. Advantageously, this can allow for a greater variety of substrates or coatings to be used.

In some embodiments, various processes can be used to improve diamond or other film quality. These processes can be done, for example, before seeding, before layer deposition, after layer deposition, or after metrology steps that contaminate the surface. For example, a substrate can be subjected to dry and/or wet processing, including but not limited to strong or weak acid and/or base cleaning, solvent cleaning, ultrasonic agitation, plasma cleaning, ultraviolet (UV), ozone treatment, application of tetramethyl ammonium hydroxide, or any other suitable combination of processes. Plasma cleaning can include subjecting a substrate to plasma derived from argon and/or oxygen in various concentrations. Post diamond deposition cleaning processes can be included such as: solvent clean that includes solvents such as: acetone and IPA, and plasma clean with O₂/Ar gases using RIE or similar to clean the substrates to remove any unwanted residue deposited during the diamond deposition processes.

In some embodiments a glass or other substrate can support multiple thin diamond layers, or thin single or multiple layers of metals, ceramics, glasses, or other compositions. Thickness of such layers can be less than 1000 nanometers. Such layers can act as cap layers, intermediate layers, or buffer layers, and can improve optical, electrical, thermal, or mechanical properties of the multilayer structure. In some embodiments, cap, intermediate, or buffer layers can be transparent and include one or more of metals (e.g., tungsten or titanium); ceramics, dielectric materials, or glass (e.g., aluminosilicate or borosilicate). In some embodiments, cap layers, intermediate layers, or buffer layers can include one or more of indium tin oxide, aluminum oxide, oxynitrides, titanium oxides including but not limited to titanium dioxide, magnesium oxide, silicon dioxide, and hafnium oxide. In other embodiments, cap layers, intermediate layers, or buffer layers can include one or more of nitrides of aluminum, silicon, titanium, or boron. Cap layers, intermediate layers, or buffer layers can also include but are not limited to carbon film formed of diamond-like carbon (DLC), amorphous carbon or nano-crystal diamond (NCD), or a metal film made of molybdenum, titanium, tungsten, chromium or copper, or a ceramic film formed of SiC, TiC, CrC, WC, BN, B4C, Si₃N₄, TIN, CrN, SiCN, or BCN. The thickness of cap layers, intermediate layers, or buffer layers can range from 2 nanometers to 1000 nanometers.

In some embodiments, a deposited diamond film can be cleaned, and exposed to a two dimensional top layer material, such as reduced fluorinated graphene oxide, graphene, graphene oxide, or f-silane. In some embodiments this provides for superhydrophobicity or oleophobicity without significant degradation to diamond film properties, including optical transmissivity and/or hardness. In one embodiment, graphene oxide may come from a chemical suspension of multilayer graphene oxide and spun on to the diamond film, and either wet chemically or dry chemically (plasma) reduced through inclusion of fluorine atoms into the material, in substitution to oxygen.

In some embodiments, a substrate and/or diamond layer may be subjected to surface functionalization treatment steps. This can include surface functionalization by wet chemistry using spray coating, biased spray coating, ultrasonic spray coating, ultrasonic agitation of solvent and ketone mixtures, including but not limited to methanol, acetone, isopropyl alcohol, ethanol, butanol, or pentanol. The functionalized surface can include hydrocarbon chains, hydroxyl bonds, oxygen termination, or other suitable chemically active materials.

In some embodiments, a substrate and/or diamond layer may be subjected to surface functionalization treatment steps. This can include surface functionalization by wet chemistry using spray coating, biased spray coating, ultrasonic spray coating, ultrasonic agitation of solvent and ketone mixtures, including but not limited to methanol, acetone, isopropyl alcohol, ethanol, butanol, or pentanol. The functionalized surface can include hydrocarbon chains, hydroxyl bonds, oxygen termination, or other suitable chemically active materials.

In some embodiments, single or multiple diamond layers or films can include additional multilayer structures that enable or enhance various usages or features, including those that provide for light redirection, interference, cover glass, protective covers, displays, windows, chemical, thermal, or mechanical protection. Applications or components supporting multilayer diamond layers, films, or coatings can include but are not limited to visible or infrared optics, windows, optical waveguides, semiconductors, semiconductor coatings, and rugged or durable coatings for electronics, manufacturing, or tooling. Other applications for diamond multilayer coatings can include use in biological substrates or medical devices, or use in batteries, fuel cells, electrochemical systems, chemo-sensors, general sensing, or integration with other advanced materials.

In the foregoing description, reference is made to the accompanying drawings that form a part thereof, and in which is shown by way of illustration specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The foregoing detailed description is, therefore, not to be taken in a limiting sense.

Reference throughout this specification to “one embodiment,” “an embodiment,” “one example,” or “an example” means that a particular feature, structure, or characteristic described in connection with the embodiment or example is included in at least one embodiment of the present disclosure. Thus, appearances of the phrases “in one embodiment,” “in an embodiment,” “one example,” or “an example” in various places throughout this specification are not necessarily all referring to the same embodiment or example. Furthermore, the particular features, structures, databases, or characteristics may be combined in any suitable combinations and/or sub-combinations in one or more embodiments or examples. In addition, it should be appreciated that the figures provided herewith are for explanation purposes to persons ordinarily skilled in the art and that the drawings are not necessarily drawn to scale.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

We claim:

1. A method of forming a diamond coated glass structure, comprising:
providing a glass substrate having a first and a second side;
coating the second side with a coating capable of reducing ion exchange;
bending the substrate to form the first side as convex and the second side as concave;
depositing a CVD diamond layer on the convex first side of the substrate; and
chemically modifying at least a portion of the substrate through ion exchange.

2. The method of claim 1, wherein bending the substrate uses asymmetrically applied mechanical force.

3. The method of claim 1, wherein bending the substrate uses thermal heating of the substrate.

4. The method of claim 1, wherein the coating capable of reducing ion exchange is silicon dioxide.

5. The method of claim 1, wherein at least one of nanocrystalline and ultrananocrystalline diamond is deposited on the convex first side of the substrate.

6. The method of claim 1, wherein chemically modifying the substrate through ion exchange comprises replacement of at least some sodium ions with potassium ions.

7. A diamond coated glass structure suitable for chemical modification by ion exchange, comprising:
a glass substrate having a first and a second side;
a coating capable of reducing ion exchange applied to at least a portion of the second side;
a CVD diamond layer applied to at least a portion of the first side of the substrate; and wherein
the glass substrate is bent to form the first side as convex and the second side as concave.

8. The diamond coated glass structure of claim 7, wherein the CVD diamond layer comprises at least one of nanocrystalline and ultrananocrystalline diamond.

9. The structure of claim 7, wherein the CVD deposited diamond layer comprises a nanocrystalline diamond layer having thickness between 20 and 500 nanometers.

10. The structure of claim 8, wherein the CVD deposited diamond layer comprises a 100-500 nanometer thick CVD deposited diamond layer having at least 50% of diamond grains sized between 10 nanometers and 150 nanometers.

11. The structure of claim 7, wherein the ultrananocrystalline diamond layer has thickness up to 50 nanometers.

12. The structure of claim 7, wherein combination of the CVD deposited diamond layer and the glass substrate provides transmission of light with a transmissivity in excess of at least one of 0.80 at wavelengths ranging between 500 and 600 nanometers.

13. The structure of claim 7, wherein the glass substrate has a dimension of at least one centimeter.

14. The structure of claim 7, wherein the glass substrate comprises at least one of a soda lime glass, aluminosilicate glass, and borosilicate glass.

15. The structure of claim 7, wherein the glass substrate is chemically modified by replacement of at least some sodium ions with potassium ions.
